(19) United States
(12) Patent Application Publication
(10) Pub. No.: US 2023/0273821 A1
(43) Pub. Date: Aug. 31, 2023

(54) MULTI-MECHANISM COOLING MODULATION DERIVED FROM INTELLIGENT JOB PLACEMENT

(71) Applicant: Intel Corporation, Santa Clara, CA (US)

(72) Inventors: Amruta MISRA, Bangalore (IN); Francesc GUIM BERNAT, Barcelona (ES); Kshitij A. DOSHI, Tempe, AZ (US); Marcos E. CARRANZA, Portland, OR (US); John J. BROWNE, Limerick (IE); Arun HODIGERE, Bangalore (IN)

(21) Appl. No.: 18/136,262

(22) Filed: Apr. 18, 2023

(51) Int. Cl. G06F 9/48; G06F 11/34

(52) U.S. Cl. CPC G06F 9/4893; G06F 11/3433

(57) ABSTRACT

A method is described. The method includes dispatching jobs across electronic hardware components. The electronic hardware components are to process the jobs. The electronic hardware components are coupled to respective cooling systems. The respective cooling systems are each capable of cooling according to different cooling mechanisms. The different cooling mechanisms have different performance and cost operating realms. The dispatching of the jobs includes assigning the jobs to specific ones of the electronic hardware components to keep the cooling systems operating in one or more of the realms having lower performance and cost than another one of the realms.

### BACKGROUND OF THE INVENTION

With data center computing environments dissipating increasing amounts of heat, system managers are increasingly interested in controlling the costs of cooling a data center while sufficiently cooling the data center's electronic hardware.

### BRIEF DESCRIPTION OF THE DRAWINGS

FIG. 1 shows an electronic system and a multi-mechanism cooling system;

FIG. 2 shows different performance and cost operating realms of a multi-mechanism cooling system;

FIG. 3 shows different electronic hardware components;

FIGS. 4a and 4b pertain to a first job dispatching process;

FIGS. 5a, 5b, 5c, 5d and 5e pertain to a second job dispatching process;

FIG. 6 shows a first data center implementation;

FIGS. 7a, 7b, 7c, 7d, 7e and 7f pertain to a third job dispatching process;

FIG. 8 shows processing activity levels of an electronic hardware component;

FIG. 9 shows a second data center implementation;

FIG. 10 shows a third data center implementation;

FIG. 11 shows a scheduled maintenance system;

FIG. 12 depicts a data center hardware platform with containerized applications.

### DETAILED DESCRIPTION

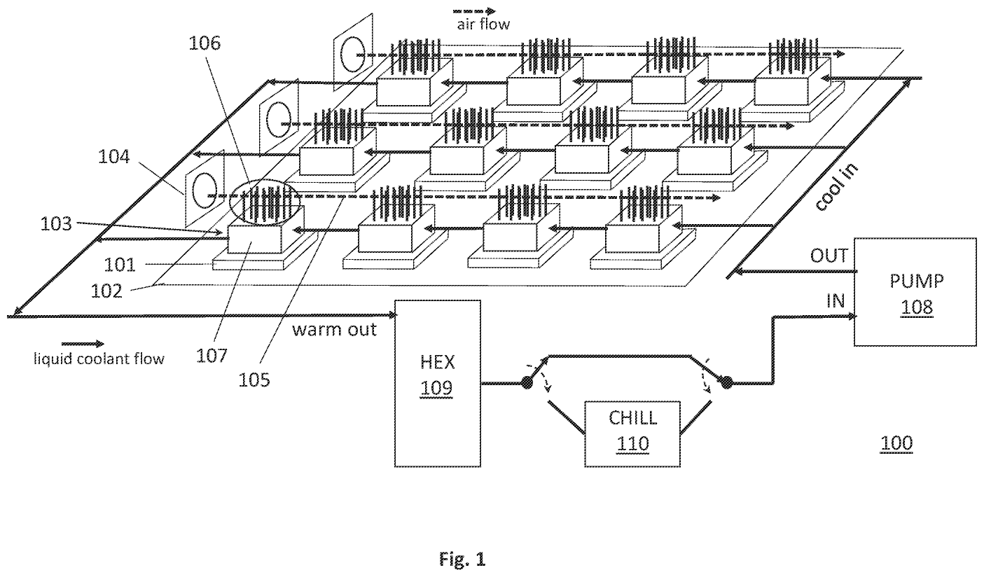

FIG. 1 depicts a multi-mechanism cooling system that is thermally coupled to an electronic system 100. The particular multi-mechanism cooling system of FIG. 1, has three different cooling mechanisms: 1) air-cooled; 2) liquid cooled; and, 3) chilled liquid cooled.

As observed in FIG. 1, the electronic system includes a number of semiconductor chip packages 101 that are electrically and mechanically coupled to an electronic printed circuit board 102. The chip packages 101 are thermally coupled to respective chip package cooling units 103 that receive heat from the one or more semiconductor chips that operate within their respective chip package 101.

In the case of the first cooling mechanism (air-cooled), a fan 104 blows ambient air 105 through fins 106 that extend from the base 107 of a chip package cooling unit 103. Here, the base 107 of the cooling unit 103 acts as a thermal mass that draws heat from the semiconductor chip(s) that operate within the chip package 102 that the base 107 is thermally coupled to. The heat is transferred from the base 107 to the fins 106 which radiate the heat into the ambient air. The air flow 105 through the fins 106 removes the heat from cooling unit 103, which in turn, removes heat from the chips within the package 102. Thus, in the case of the first mechanism, the cooling unit 103 acts as a traditional heat sink.

In the case of the second mechanism (liquid cooling), liquid flows through the base 107 of the cooling unit 103 which acts as a cold plate. Here, heat generated by the semiconductor chip(s) is drawn into the base 107 of the cooling unit 103 while liquid flows through one or more fluidic conduits that are formed within the base 107 of the cooling unit (the liquid is pumped by pump 108). The liquid is warmed from the heat and then flows out of the base 107 thereby removing heat from the cooling unit 103. The warmed liquid is then channeled to a heat exchanger 109 (“hex”). The heat exchanger 109, e.g., ripples the warmed fluid over fins that are exposed to the ambient which reduces the temperature of the fluid. The cooled fluid is then channeled back to the base 107 and the process repeats.

In the case of the third mechanism (chilled liquid cooling), the same approach as liquid cooling above is applied except that the cooled fluid runs through both the heat exchanger 109 and a chilling unit 110. Here, the heat exchanger 109 can theoretically only lower the temperature of the liquid to that of the ambient temperature. That is, the heat exchanger 109 is essentially a passive device that relies on the ambient as a heat sink.

By contrast, in the case of chilled liquid cooling, energy is applied to an active cooling unit 110 (a chiller, chilling unit, etc.) that can reduce the temperature of the warmed fluid beneath ambient temperature.

For ease of explanation FIG. 1 depicts a cooling unit in which a single semiconductor chip package 102 is coupled to a single cooling unit 103. However, in other solutions multiple chip packages can be coupled to a same cooling unit base 107, and/or, multiple cooling units 103 can be coupled to a single chip package 102. Similarly, although FIG. 1 depicts four cooling units per fan, four cooling units per branch of cooled liquid flow, and twelve cooling units per pump/hex/chiller, other approaches can have different numbers for each of these particular cooling designs.

The three different cooling mechanisms effect three different “course grain” adjustments that can be used to effect various tradeoffs between cooling performance and cooling cost. Specifically, air cooling represents the least performance but the lowest cost, chilled cooling represents the highest performance but the highest cost, and liquid cooling falls in between these two extremes.

More specifically, among the three mechanisms, heat is removed from the system least effectively with air cooling, but, the cost to run the fans 104 with air cooling is less than the cost of running the pump 108 with liquid cooling or the cost of running the pump 108 and the chiller 110 with chilled liquid cooling. By contrast, heat is removed from the system most effectively with chilled liquid cooling, but the cost of running the pump 108 and the chiller 110 exceeds the cost of the running just the pump 108 with liquid cooling or the fans 104 with air cooling. With respect to liquid cooling, heat is removed more effectively than air cooling but less affectively than chilled liquid cooling, while, the cost of running the pump 108 is more expensive than the cost of running the fans 104 but less expensive than the cost of running both the pump 108 and chiller 110.

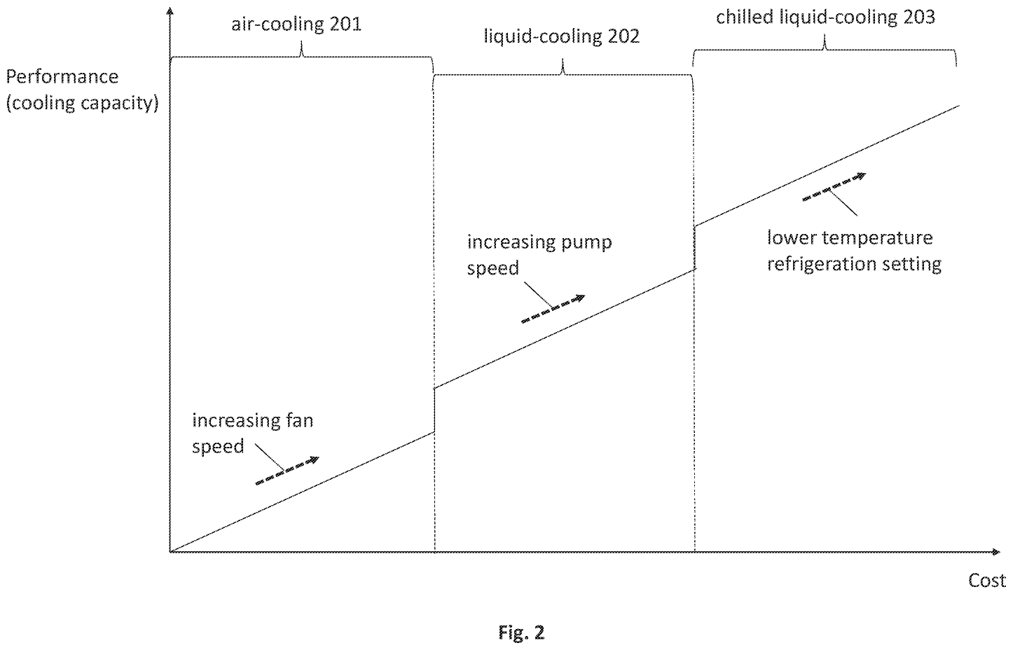

FIG. 2 shows the range of different performance/cost tradeoffs that can realized for the electronic system of FIG. 1 when “fine grained” adjustments within each cooling mechanism are accounted for. Here, three course grained regions 201, 202, 203 correspond to air cooling in the lowest performance/cost region 201, liquid cooling in the middle performance/cost region 202, and chilled liquid cooling in the highest performance/cost region 203.

Notably, however, each different cooling mechanism can have its own range of performance/cost tradeoff. Specifically, if the speed of the fans are adjusted up/down, then, the performance/cost of the air cooling 201 is likewise adjusted up/down. Similar adjustments can be made by adjusting the pumping action (pump speed) during liquid cooling 202 and adjusting the chiller's temperature setting during chilled liquid cooling 203.

For ease of discussion, the simple example of FIG. 2 assumes that maximum air cooling (maximum fan speed) is applied whenever liquid cooling 202 or chilled liquid cooling 203 is applied, and that, maximum liquid cooling (maximum pump speed) is applied whenever chilled liquid cooling 203 is applied. Other systems may choose to concurrently impose adjustments to two or more of the cooling mechanisms to realize a more complicated arrangement of tradeoffs.

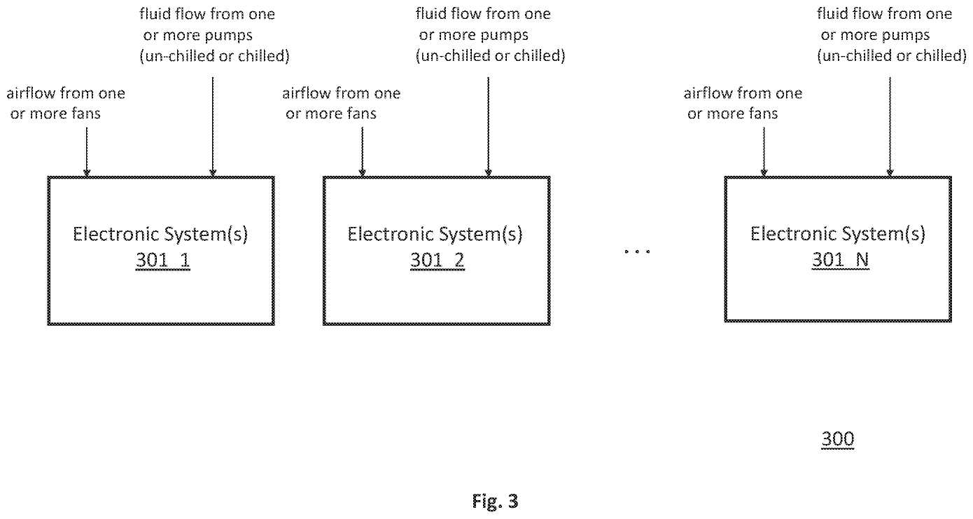

FIG. 3 shows a schematic view of a data center 300 having multiple electronic systems 301 whose respective cooling systems can implement multi-mechanism cooling. According to the schematic view of FIG. 3, each box 301_1, 301_2, . . . 301_N corresponds to a unit of electronic system hardware that is cooled with a respective cooling system that is capable of multi-mechanism cooling. As such, each box 301 can receive air flow from a one or more fans and can receive cooling fluid (chilled or un-chilled) from one or more pumps.

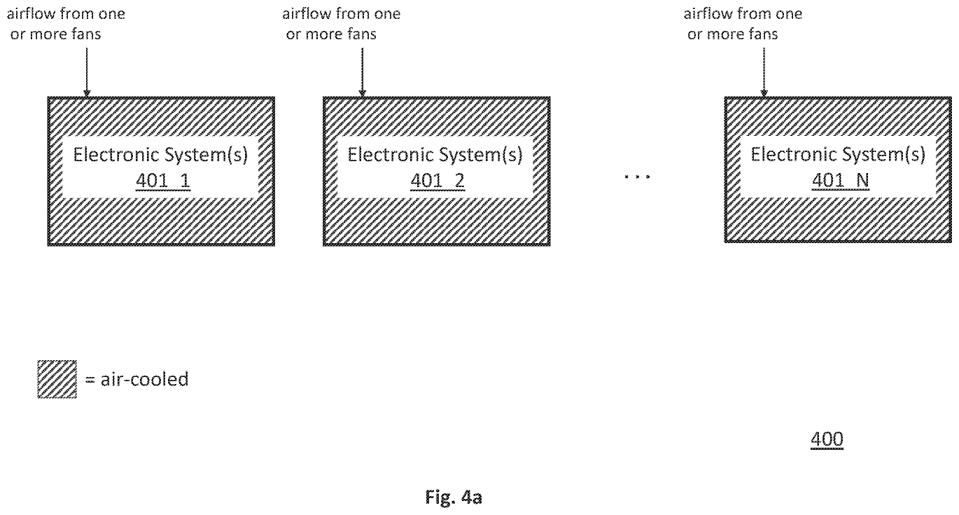

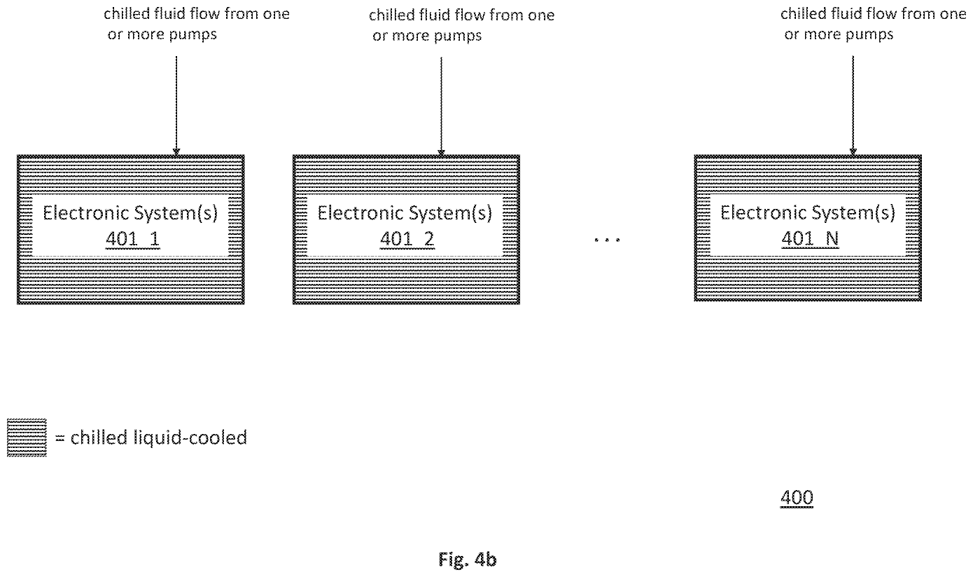

Here, each box 301 can represent an electronic hardware component at any of multiple possible granularities. For example, a single box 301 can represent any of: 1) a semiconductor chip package; 2) multiple semiconductor chip packages coupled to a same cooling apparatus (e.g., as observed in FIG. 1); 3) an integrated electronic system, e.g., within a same chassis, having multiple semiconductor chip packages where the system include(s) one or more cooling systems to cool the system's chips (e.g., a rack mountable CPU sled, a rack mountable memory sled, a rack mountable non-volatile mass storage sled, a rack mountable acceleration sled, a rack mountable sled of infrastructure processing units (IPUs), a rack mountable blade server, etc.); 4) a collection of systems as described in 2) or 3) just above, such as, a rack of CPU sleds, a rack of memory sleds, a rack of mass storage sleds, a rack of blade servers, etc. Here although the terms “electronic system(s)” are used in each of FIGS. 3, 4a-b, 5a-e, 6, 7a-f, 8, 9 and 10, it should be understood that the individual boxes of these FIGS. 301, 401, 501, 601, 701, 801, 901, 1001 can correspond to any of the possibilities of 1) thru 4) as well as other electronic equipment integrations.

For ease of discussion, much of the remaining discussion will be directed to an example where each box represents a rack of systems as described in 4) above where the rack contains, e.g., CPU sleds installed therein. Here, each rack has an associated number of fans, pumps and chillers to effect multi-mechanism cooling of the various systems that are plugged into the rack.

With each rack being capable of multi-mechanism cooling at rack granularity, the data center 300 of FIG. 3 is capable of different cooling configurations to, e.g., strike a concise (e.g., optimized) balance between the functional demands placed upon the data center, and, the costs incurred to cool the data center.

FIGS. 4a and 4b explore two possible configurations. FIG. 4a shows a first data center 400 configuration (operating state). As observed in FIG. 4a, all of the hardware units 401 are being air-cooled. In this case, e.g., the data center's entire cooling apparatus is placed in the lowest coarse grained performance and cost state. The state of FIG. 4a can be entered, e.g., if the data center is hardly being utilized. An example includes a business that relies heavily on the data center during working hours (e.g., 9:00 AM to 5:00 PM) but hardly uses the data center during non working hours. In this case, the data center state of FIG. 4a is appropriate during the non-working hours.

FIG. 4b shows a second configuration. Here, all of the hardware units 401 are being cooled in the chilled liquid cooled state. In this case, e.g., the data center's entire cooling apparatus is placed in the highest coarse grained performance and cost state. The state of FIG. 4b can be entered, e.g., if the data center is being maximally utilized (e.g., the working hours of the aforementioned data center of FIG. 4a). Other data center cooling configurations between the two extremes of FIGS. 4a and 4b are also possible.

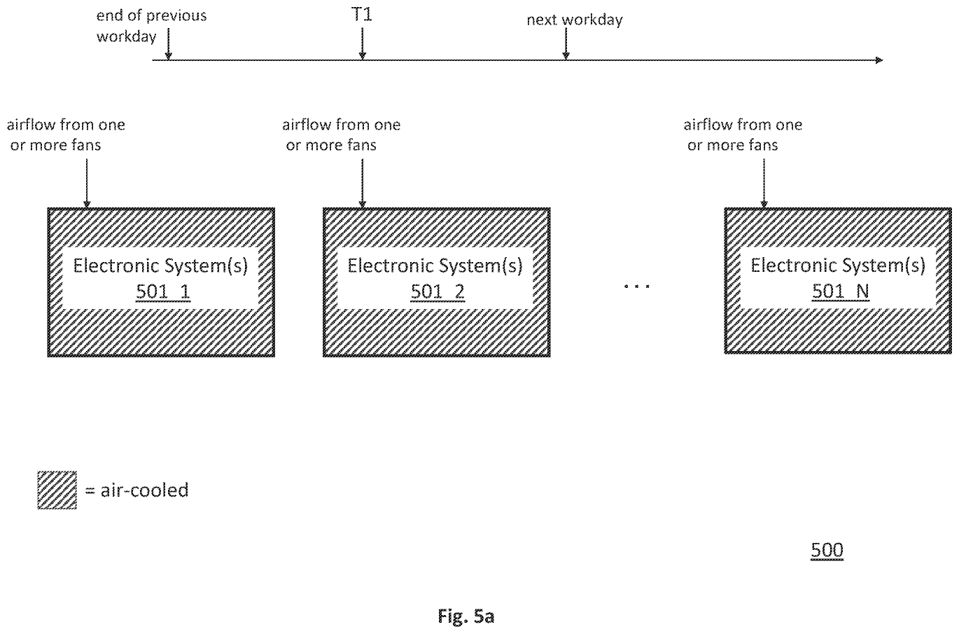

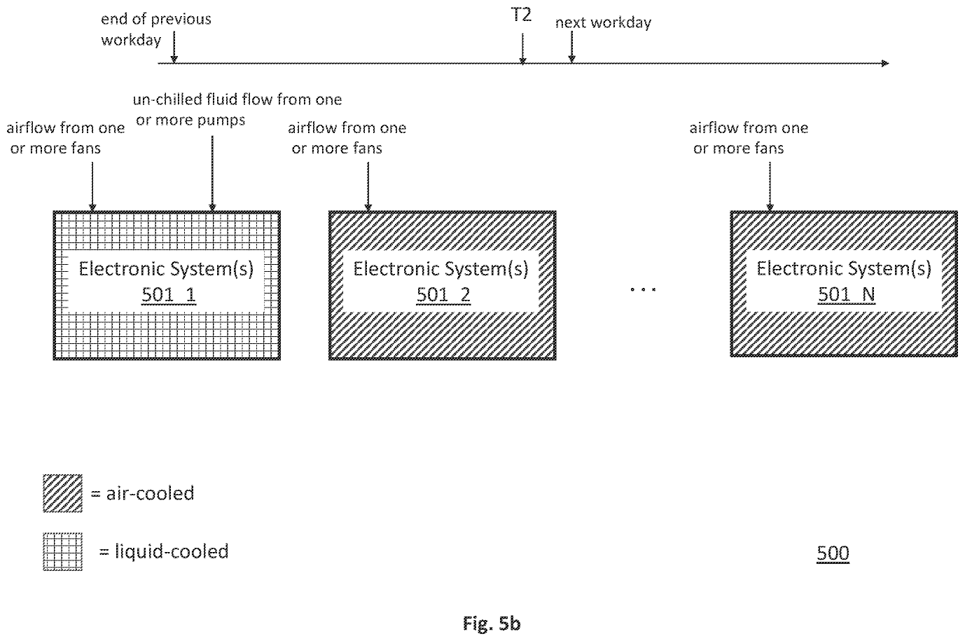

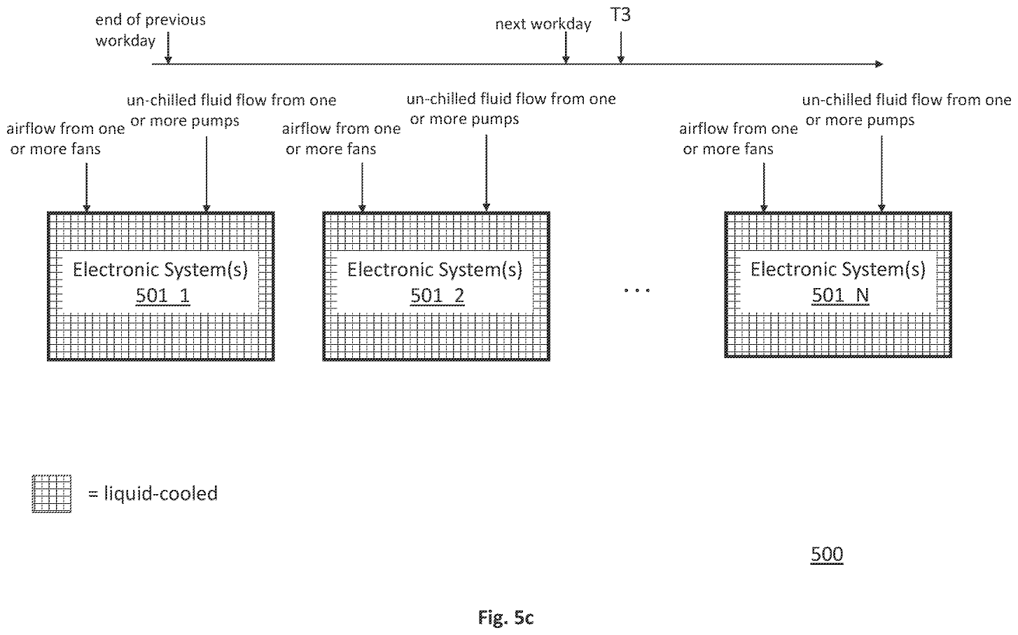

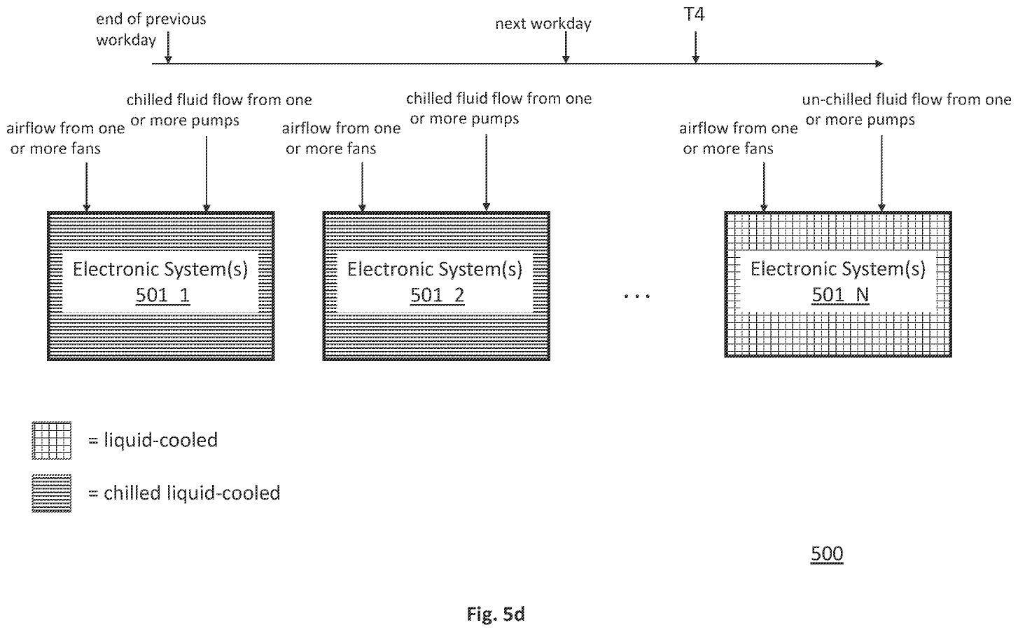

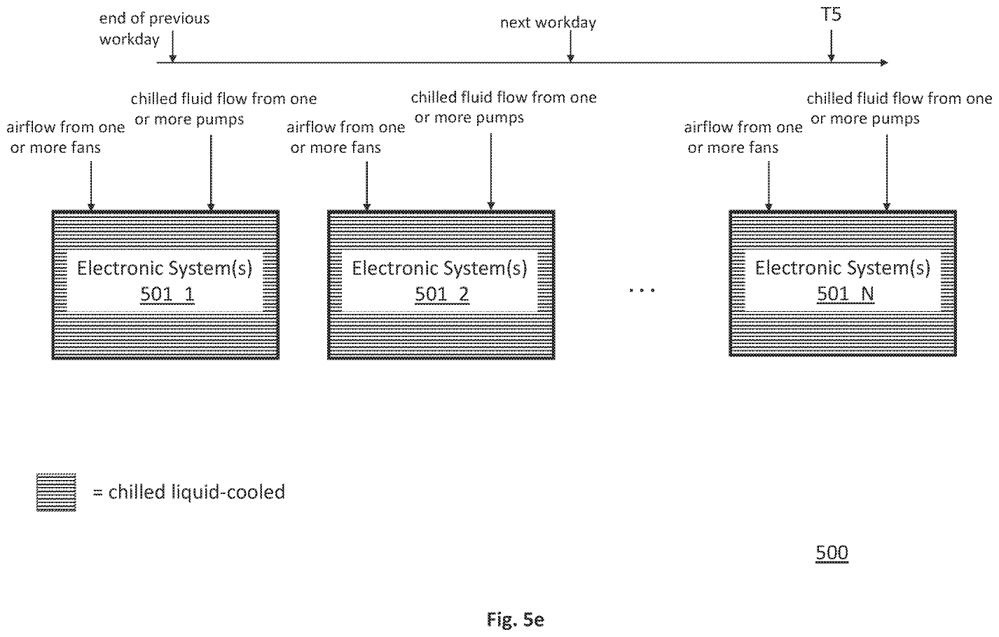

Here, FIGS. 5a through 5e depict different cooling configurations as the aforementioned data center's 500 work load gradually rises during non work hours just before work hours, continues to rise during work hours until reaching a maximum in the middle of the work data, and then begins to gradually decline towards the end of work hours and then through the end of work hours into a next timespan of non work hours.

In this example, FIG. 5a represents a time T1 midway between the previous work day's end and the next, upcoming work day's start. In this case, the data center's cooling state is placed in the lowest state described above with respect to FIG. 4a. Then, as observed in FIG. 5b, at a time T2 just before the start of the next day's working hours, the data center's workload has increased to the point where it is appropriate to cool a first rack 501_1 with liquid cooling rather than air cooling.

Then, as observed in FIG. 5c, at time T3, e.g., a few hours after the start of working hours, the data center's workload has increased to the point where it is appropriate to cool all of the racks 501 with liquid cooling rather than air cooling. Then, as observed in FIG. 5d, at time T4, e.g., midway between the start of the workday and the middle of the workday, the data center's workload has increased to the point where it is appropriate to cool a few racks 501_1, 501_2 with chilled liquid cooling rather than liquid cooling. Then, as observed in FIG. 5e, at time T5, e.g., midway between the start of the workday and the end of the workday, the data center is receiving maximum workload where it is appropriate to cool all of the racks 501_1, 501_2, through 501_N with chilled liquid cooling.

Then, after the workday's midpoint (T5), the above described process occurs in reverse where: 1) the cooling configuration FIG. 5d represents an appropriate configuration midway between the workday's midpoint and the end of the workday; 2) the cooling configuration of FIG. 5c represents an appropriate cooling configuration just before the end of the workday; 3) the configuration of FIG. 5b represents an appropriate cooling configuration just after the workday; etc.

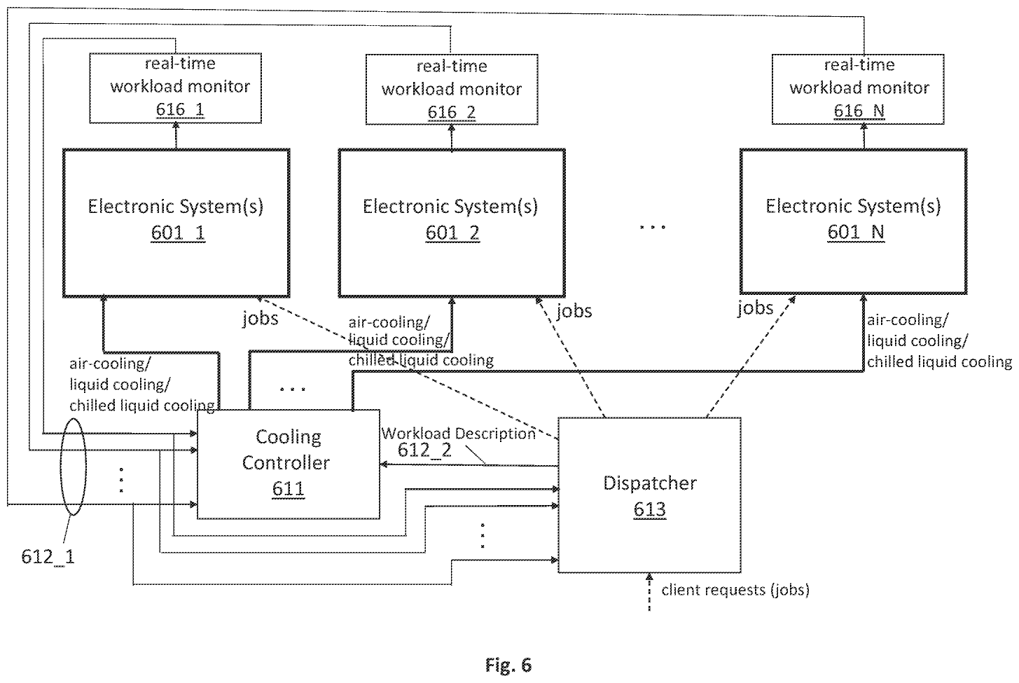

FIG. 6 shows a high level view of a data center 600 that includes a cooling system controller 611 that can implement workload based modulation of the data center's cooling configuration as described just above. As observed in FIG. 6, the cooling system controller 611 receives input information 612_1, 612_2 that describes the data center's workload (current and/or future), and, based on the input information 612_1, 612_2, configures the data center's cooling system into an appropriate configuration for the workload.

In the case of current workload information, for each individual rack, the cooling system controller can receive various metrics from the rack's real time workload monitor 616 that describes the rack's current operational state (e.g., temperature, processor activity (e.g., instructions per second, processor frequency), memory activity (e.g., memory access reads and/or writes per second), power supply current draw, jobs being processed by the rack's constituent systems, etc.). Based on these metrics the cooling system controller 611 can access the cooling needs of the individual racks and adjust each rack's cooling system, accordingly.

As observed in FIG. 6, the data center also includes a dispatcher 613. The dispatcher 613 receives the data center's input processing requests (jobs) and dispatches the jobs to the racks 601_1 through 601_N according to some kind of dispatching process. Importantly, in various embodiments, the dispatcher's dispatching process attempts to keep the data center's total cooling cost across all the racks 601_1 through 601_N at a minimal level.

Here, each job causes the rack that processes the job to perform some amount of work (“processing activity”) which, in turn, causes the rack's electronic hardware to emit some additional heat that the rack's cooling system will have to remove. As the number of jobs that a rack receives grows, the cooling demands will necessitate a higher performance/cost setting for the rack's cooling.

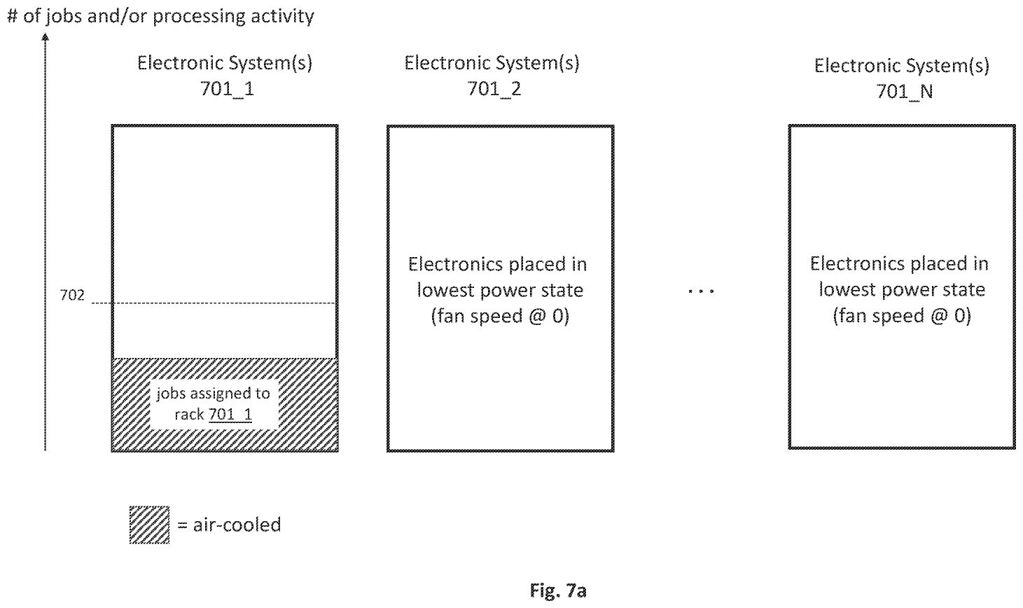

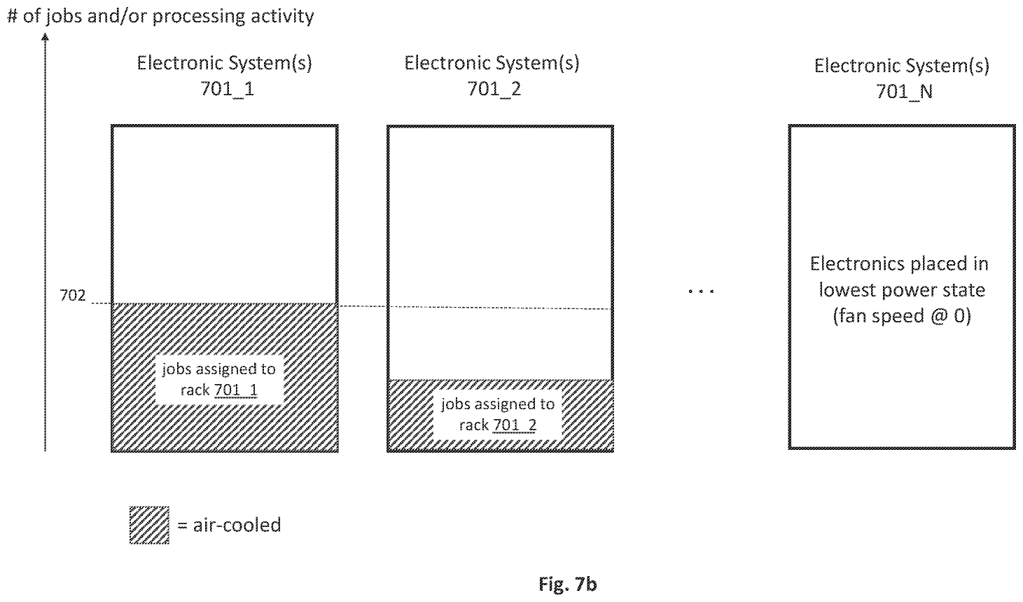

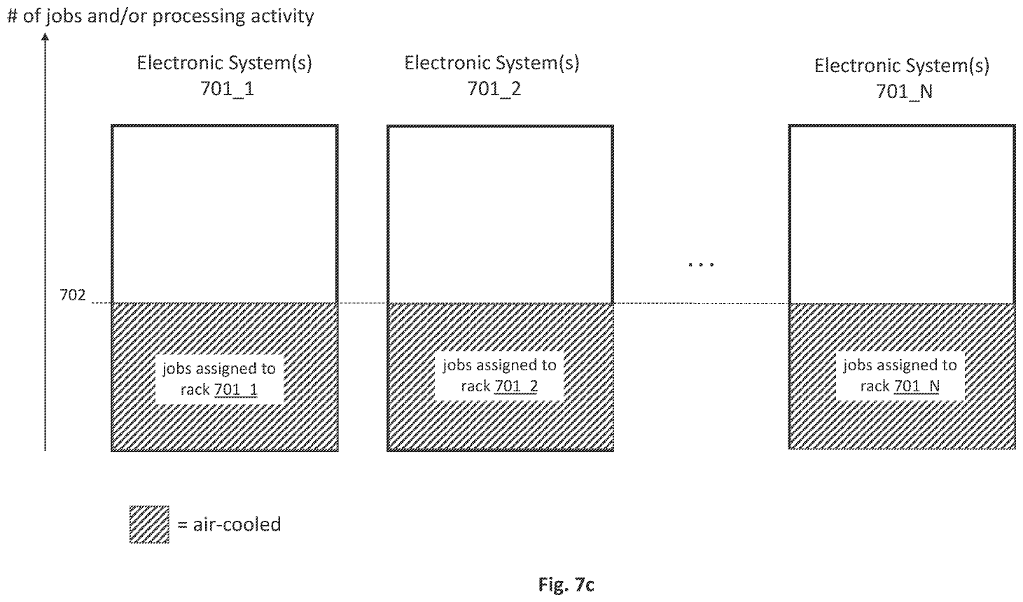

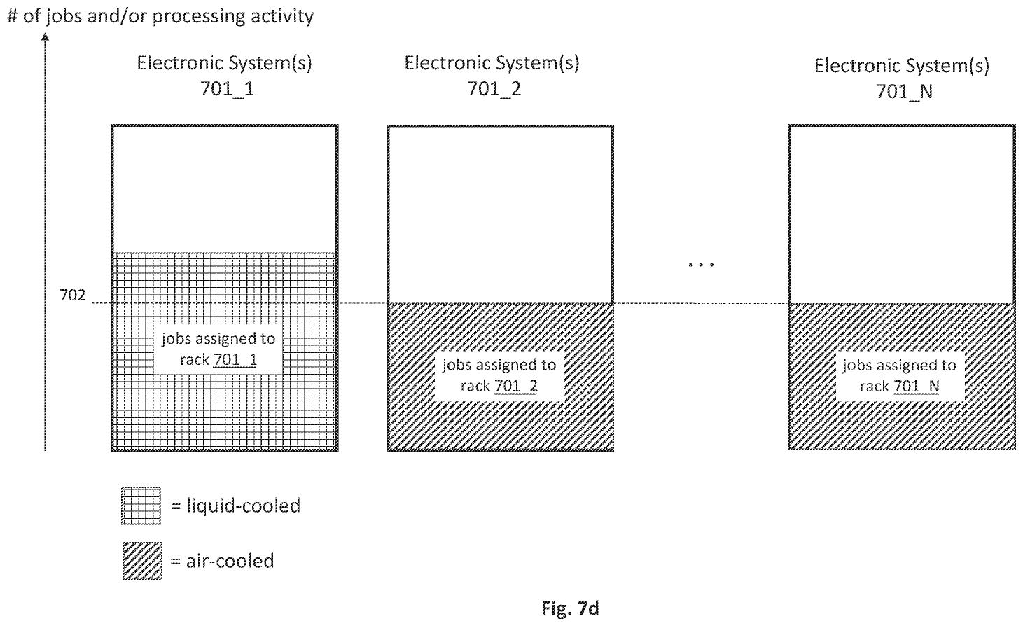

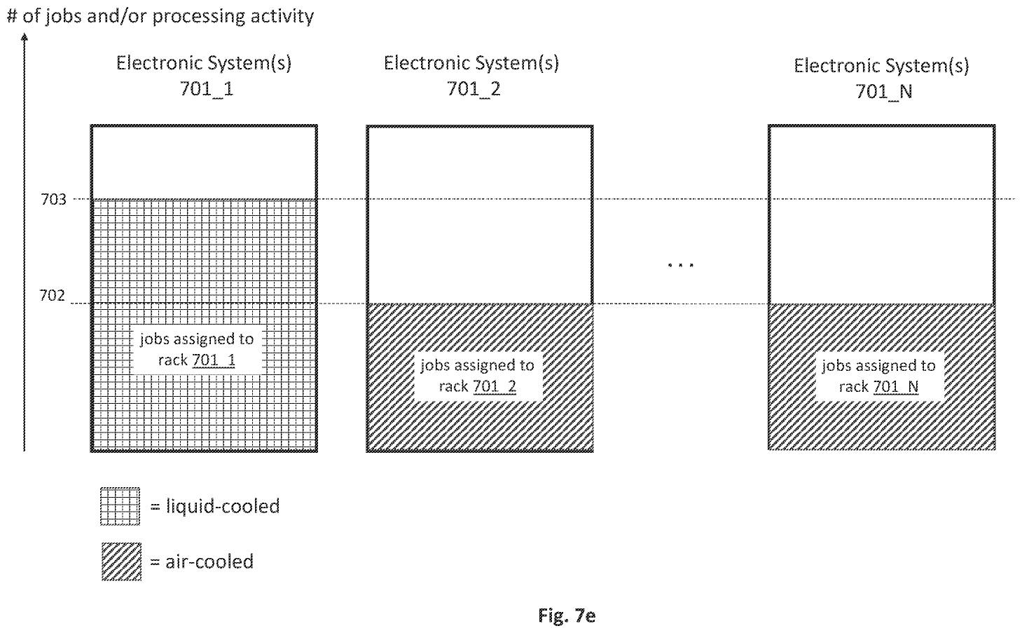

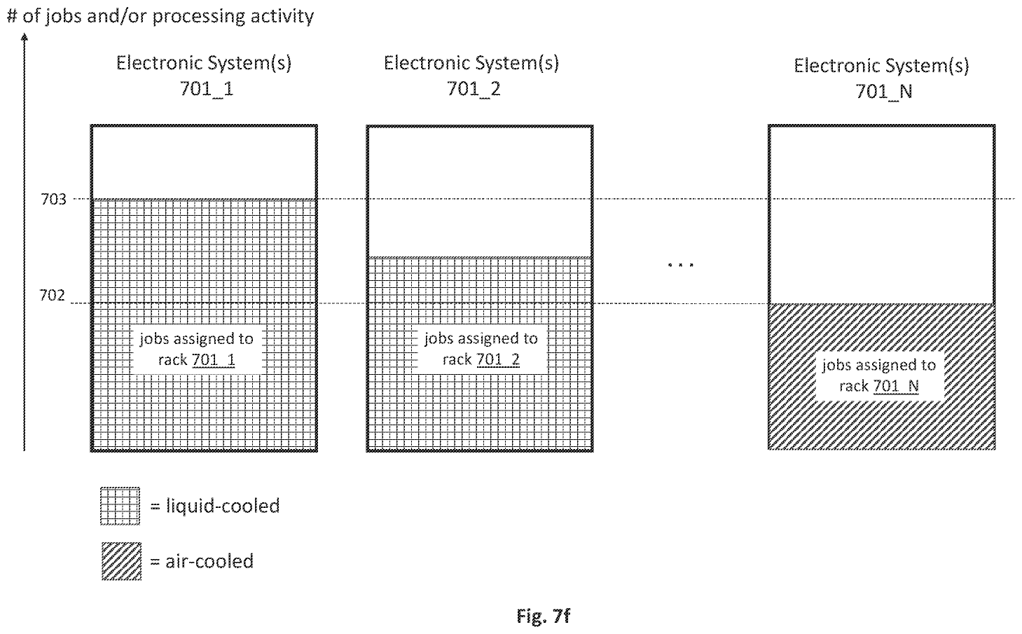

FIGS. 7a through 7f pertain to various dispatching processes that the dispatcher 613 can be configured to perform.

According to a first dispatching process, observed in FIG. 7a, when starting from a zero workload state in which the data center is not processing any jobs, the dispatcher 613 attempts to assign the jobs only to a first rack 701_1 up to some (e.g., predefined) number of jobs 702. By assigning all jobs to one rack, the remaining racks 701_2 through 701_N can remain in the lowest possible cooling performance/cost state (e.g., fan speed=0). More specifically, the electronic systems with the racks that are not assigned any jobs 701_2 through 701_N can be held, e.g., in their lowest power consuming state (e.g., the systems' respective semiconductor chips are placed in a lowest power state and deepest sleep state with little/no clock activity). So doing keeps the average cooling cost per job minimal across the data center.

Here, the first rack 701_1 that is assigned all new jobs steadily increases its need for cooling as jobs are assigned to it. However, at least in the early stages when the data center is under light total workload, the one rack remains in the lower performance/cost region (air cooled) and merely increases its fan speed to maintain sufficient cooling while the remaining racks 701_2 through 701_N hardly consume any power at all and require essentially no cooling.

Referring to FIG. 7b, once the number of jobs reaches the predefined level 702, the dispatcher 613 begins assigning new jobs to a second rack 701_2. According to a further embodiment, the number of jobs 702 that triggers the switchover to the second rack 701_2 is the number of jobs that keeps the first rack 701_1 within the lower performance/cost region (air cooled). That is, said another way, if the dispatcher 613 continued to dispatch jobs beyond the predefined number 702 it would trigger the cooling system of the first rack 701_1 into the next higher performance/cost cooling state (liquid cooling). Thus, in order to minimize cooling cost per job, the dispatcher 613 begins directing jobs to the second rack 701_2 so that air cooling is used for all jobs.

The dispatching process then continues in this manner until, as observed in FIG. 7c, all racks are processing jobs within the lowest performance/cost cooling state (for ease of explanation, all racks are assumed to have a same switchover level 702).

As the rate of new jobs being received by the data center continues to increase, as observed in FIG. 7d, the dispatching process begins assigning new jobs only to the first rack 701_2 which triggers the cooling of the first rack 701_1 to switchover to the next higher performance/cost cooling state (liquid cooled). Eventually, as observed in FIG. 7e, a second level 703 is reached beyond which the first rack's cooling state would need to trigger into the highest performance/cost state (chilled liquid cooling), at which point, as observed in FIG. 7f, the dispatcher 613 begins dispatching jobs to the second rack 701_2.

The process then continues as before until all racks are being cooled in the medium performance/cost state. If the rate at which jobs are being sent to the data center continues to increase the dispatcher 613 can then begin sending all new jobs to the first rack 701_1 which triggers the first rack's cooling system to operate in the higher performance/cost state (chilled liquid cooling). If the rate at which jobs are being sent to the data center continues to increase the dispatcher than begins sending all new jobs to a next until the respective cooling systems of all racks are operating in the highest performance/cost state.

Note that the jobs described above correspond to the number of active jobs at a moment in time. That is, when a job is completed it reduces the number of active jobs assigned to the rack that processed the job. Thus, the above described dispatching process can weigh the rate at which jobs are being sent to the data center to determine per job rack assignment. As such, the different predetermined levels described just above can correspond to a certain amount of processing capacity within the rack (e.g., X number of CPU cores are active and/or operate beneath some higher performance state).

When the rate of incoming jobs exceeds the processing capacity of a rack that can remain properly cooled within the lowest cooling performance/cost state (e.g., level 702), the dispatcher 613 begins sending new jobs to the next rack, and so on.

The above example assumes for simplicity that all jobs induce approximately a same amount of rack processing activity. In environments where different jobs can induce different amounts of rack processing activity, each job can be assigned (e.g., by the dispatcher 613 or some other intelligence) a metric that corresponds to the amount of processing activity the job will entail on its assigned rack, the amount of power such processing activity corresponds to, and/or, the amount of heat that such power and/or processing activity will add to the rack. Thus, for instance, higher performance jobs will be assigned a higher metric (e.g., “5”) than a metric that is assigned to lower performance jobs (e.g., “3”).

The dispatcher 613 then adds the metrics that are assigned to a same rack to determine the processing activity that has been assigned to the rack. If the processing activity reaches the predetermined processing capacity of a rack within a lowest cooling performance/cost state (e.g., level 702), the dispatcher 613 will begin dispatching new jobs to a next rack, and so on.

This dispatching process not only applies to environments where the applications that are executing the jobs are the same but also where the applications that execute the various jobs can be different. Here, a job that is executed by a higher performance application can be assigned a higher metric while another job that is executed by a lower performance application can be assigned a lower metric.

A higher performance application can be characterized by an application that consumes higher CPU cores/processes/threads, more accelerator invocations, requires a larger memory footprint, and/or uses memory more extensively (greater number of memory accesses), while a lower performance application can be characterized by an application that consumes lesser amounts for these resources as described. Thus, the assignment of a metric to a job can include, at least in part, a component that weighs the performance level of the application that is to execute the job.

The above discussions have so far assumed that the metrics that are assigned to jobs are a static value that does not change over the runtime of the job. In an embodiment, the static metric corresponds to a worst case cooling need for the application (the job is assumed to consume a maximum power for the job and dissipate a maximum amount of heat for the job).

In a more complex approach, the metric that is assigned to a job can dynamically change as the application's processing needs, power consumption and/or heat dissipation change.

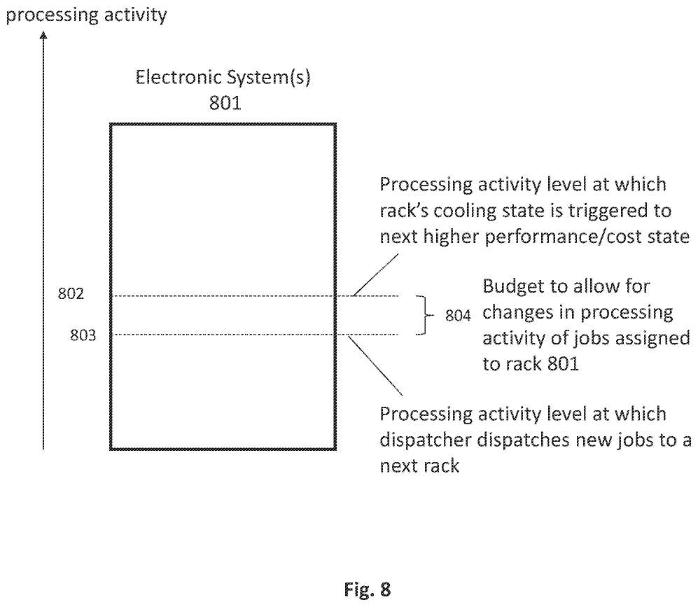

Here, according to a first approach, when a job is first dispatched by the dispatcher 613, an average or typical metric for the job is assigned to the job and the job is dispatched to a rack based on the average/typical metric. Additionally, referring to FIG. 8, some budget 804 is afforded between the processing activity of a rack that triggers a next higher performance/cost cooling state 802 and the total of all metrics assigned to a rack before the dispatcher begins assigning jobs to a next rank 803. Specifically, the total of all metrics of all jobs assigned to a rack 803 corresponds to a lower processing activity for that rack than the processing activity that would trigger a switchover to a next higher performance/cost cooling state 802 for the rack. So doing allows the jobs to dissipate some additional heat beyond what their initial metric suggests without causing the rack to switchover to a next higher performance/cooling cost state.

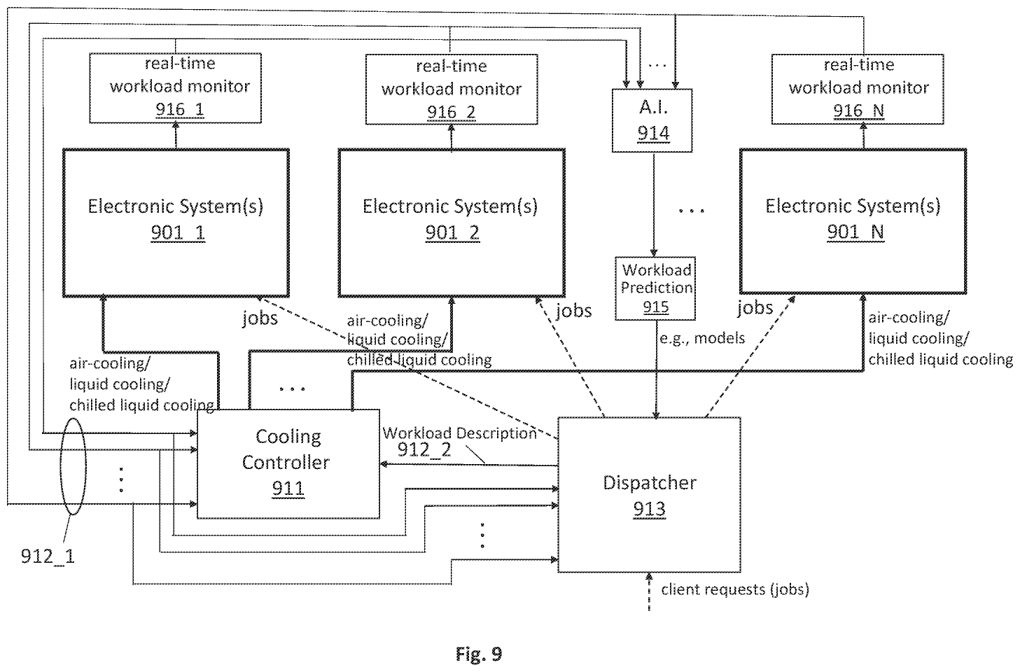

Referring to FIG. 9, any kind of machine learning, artificial intelligence or other analytic function 914 can observe/study/analyze the jobs to learn more about their metric dynamic changes over their respective runtimes. For example, certain jobs (meaning a same function call or type of function call) and/or certain applications (and/or types of application) may demonstrate repeated and therefore predictable changes in their respective processing/power needs over their respective runtimes.

Such learning can be used to adjust the metric that is assigned to a job and/or add a “delta” to the metric that informs the dispatcher 913 of how much (and in what direction) the job's processing/power needs are expected to change over the course of the job's runtime.

For example, if a job has an initial default metric of 3 and a delta of +2, the dispatcher 913 can assume the job will eventually exhibit a processing/power need that corresponds to a 5 and assign to the job to a rack accordingly. For example, based on the total of all metrics of all jobs assigned to a particular rack, if the increase from 3 to 5 could cause the rack to trigger into a next higher cooling system performance/cost state, the dispatcher 913 could decide to assign the job to a next rack whose total of all metrics is well beneath the rack's cooling state trigger point. Although this example is directed to a job (a particular session executing on a particular application), it can be extended to applications and/or containers (an application or container is assigned to a next rack based on the application's/container's metric and delta).

Alternatively or in combination, the dispatcher 913 can dynamically reassign a job to another rack as the job's processing needs dynamically change. For example, consider a situation where a first rack is already operating in a highest cooling performance/cost state and has budget to take on another high performance job, while, a particular job is executing on another, second rack that is operating with a lower cooling performance/cost state. If the processing activity of the second rack is near the trigger point at which the second rack switches over to a next higher cooling performance/state, and if the processing needs of the job increases and/or is expected to increase in the near future, the dispatcher 913 can move the job from the second rack to the first rack to avoid the switchover of the second rack's cooling state.

In another scenario, the processing activity of a first rack is operating in a higher performance/cost cooling state but near the point at which the first rack could drop down to a lower cooling performance/cost cooling state. Meanwhile, a second rack is operating in a lower performance/cost cooling state and has plenty of budget to take on more jobs without causing a switchover to a higher performance/cost cooling state. If a job executing on the first rack increases and/or is expected to increase in the near future, the dispatcher 913 can move the job from the first rack to the second rack. The removal of the job from the first rack causes the first rack to drop to a lower cooling performance/cost state rather than remain in the higher cooling performance/cost state because of the job's expected increased activity.

In another scenario, a first rack is operating in a highest performance/cost cooling state because most of its jobs are high performance jobs and second and third racks are operating in the lowest performance/cost cooling state because most of their jobs are low performance jobs. In this case, the dispatcher 913 can move high performance jobs from the first rack to the second and third racks, and, move jobs from the second and third racks to the first rack. So doing could cause the first rack to drop to a lower cooling performance/cost state while keeping the second and third racks to remain in the lowest cooling performance/cost state (e.g., if their current activity is well below their trigger point to a next higher cooling performance/cost state).

Thus, the dispatcher 913 can dynamically move jobs based on observed and/or learned/predicted changes in job processing activity to, e.g., keep the overall cooling costs of the data center at a minimum. Alternatively or in combination, a deployment controller (described in more detail below) can move a job based on dynamic workload changes as described just above. The deployment controller can move the job directly or indirectly (e.g., by moving a container that the job executes within).

As observed in FIG. 9, in the case where dynamic changes in job processing activity are predicted, the data center maintains a processing activity prediction function 915. As explained above, the predicted processing activity changes can be based on machine learning/artificial intelligence processes 914 that observe repeated patterns in processing activity.

Such predicted changes can be static (e.g., a predicted job activity profile is maintained for the job before job runtime and is relied upon by dispatcher over the course of the job's runtime). Alternatively or in combination, any predicted changes in job activity can be based on a job's current state and/or, e.g., recent activity. Thus, a real time monitoring system 916 that observes the processing activity of the jobs is real time can be used to feed forward a job's current/recent activity to the dispatcher 913, which, in turn, can influence the job's predicted future activity (e.g., as an input parameter to a predicted job activity function and/or model that was provided to the dispatcher 913 by the workload prediction function 915).

The information from the real time monitoring system 916 can also be used directly by the dispatcher 913. In this case, for example, a sudden detected increase in a job's activity (e.g., in the absence of any predicted increase) can be used by the dispatcher 913 to, e.g., move the job to another rack.

Thus, as described above, both predictions of changes in job activity and real-time observations of changes in job activity can be used by the dispatcher 913 to move jobs that are in process to different racks, e.g., as per the scenarios described just above.

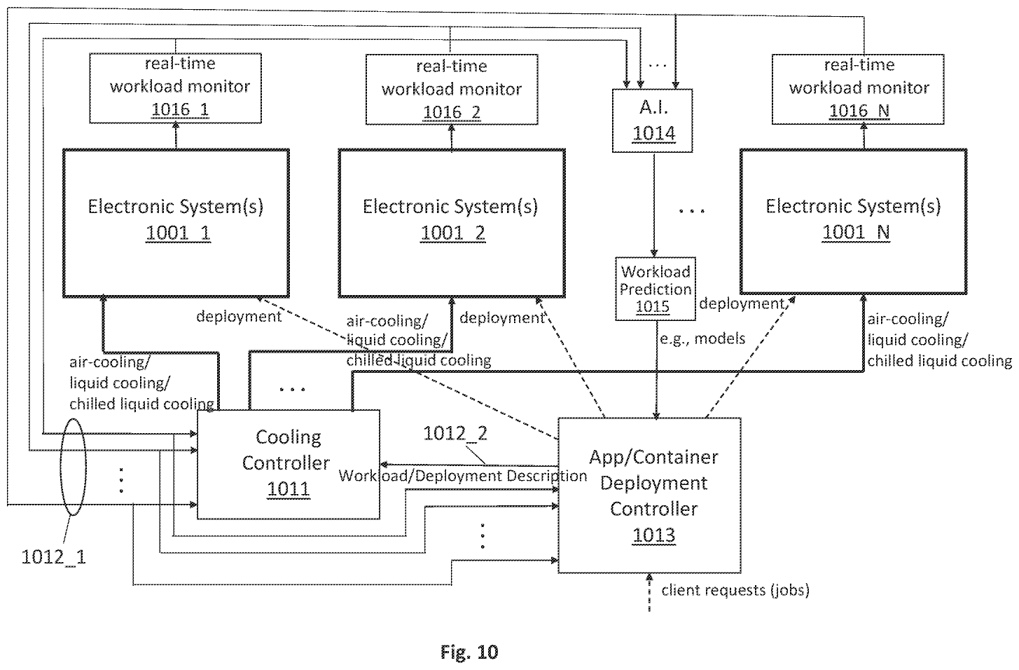

Although the dynamic movement scenarios described just above were directed to jobs specifically, the same concept can be extended to applications and/or containers (an application or container is moved based on dynamic changes in the application's or container's processing needs). In this case, referring to FIG. 10, the job dispatcher 913 of FIG. 9 is replaced, e.g., by a data center application/container deployment controller 1013. Here, the deployment controller 1013 can provide deployment information 1012 to the cooling controller 1011 which is converted by the cooling controller 1011 to an understanding of per rack workload (and/or the conversion is performed by the deployment controller 1013 and provided to the cooling controller 1011).

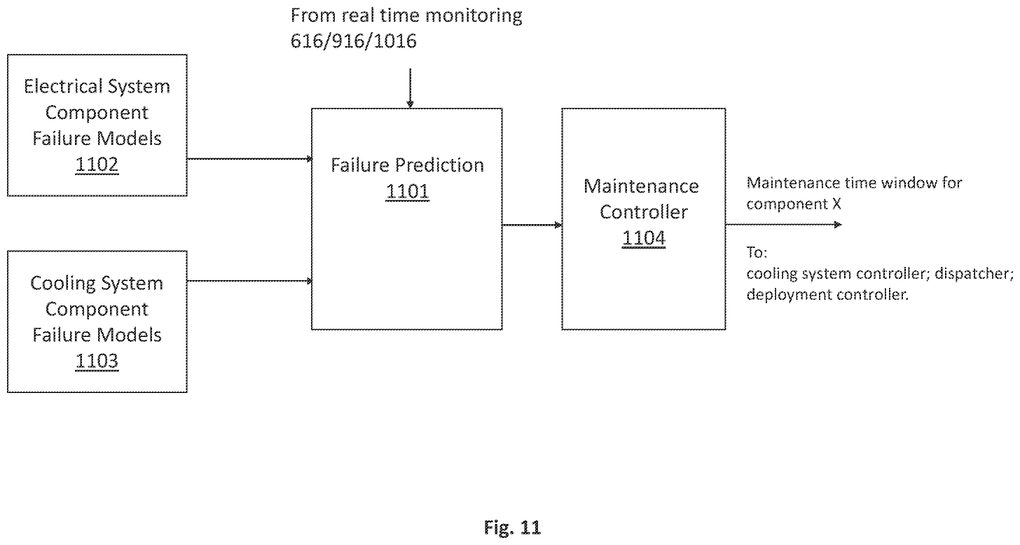

Note that the data center of FIG. 10 and the data center of FIG. 11 can be merged so that both a dispatcher 913 and a deployment controller 1013 exist in the same data center as depicted in FIGS. 10 and 11, respectively.

FIG. 11 shows maintenance scheduling functionality that can be added, e.g., to any of the data center implementations described above. Here, the data center additionally includes a failure prediction function 1101 for the rack's respective electrical components and cooling system components. Here, the aforementioned real time monitoring system 616/916/1016 feeds the failure prediction function 1101 with information that describes the actual usage/activity of the electrical/cooling components including the intensity of such usage/activity.

Here, usage/activity intensity can affect component reliability. For example, electrical components (e.g., processors, memory modules, solid state drives (SSDs), etc.) having higher average input command/instruction rates, applied clock frequencies, temperatures, supply voltages, etc. will wear-out (fail) before same kinds of electrical components having lower average input instruction/command rates/clock frequencies/temperatures/voltages. Likewise, cooling supply components that are being used more frequently (e.g., pumps, valves, lubricating oils, etc.), subjected to higher pressures (e.g., hoses, gaskets, etc.), and/or removing larger amounts of heat over time will wear-out before same kinds of cooling components that are subjected to less usage/pressures/heat. Additionally, certain kinds of cooling components can wear out over time irrespective of usage (e.g., cooling fluid, thermal interface paste, etc.).

The failure prediction function 1101 receives the actual usage information from the real time monitoring function 616/916/1016 and applies the information to wear-out models that the prediction function maintains for the data center's individual electrical components 1102 and cooling components 1103. Before any one of these components is predicated to fail, the failure prediction function 1101 sends a communication to a maintenance controller 1104 that alerts the cooling controller 611/911/1011, dispatcher 613/913 and deployment manager 1013 of the upcoming expected time of failure and/or a time window over which replacement is recommended.

The maintenance controller 1104 maintains a maintenance schedule for the data center's electrical and cooling system components that schedules replacements of the components based on the information from the failure prediction function 1101. The maintenance controller 1104 communicates the component replacement schedules to: 1) the cooling controller 611/911/1011 so the component's associated cooling system can be shut down for the replacement activity; 2) the dispatcher 613/913 so that the dispatcher will stop sending new jobs to electronic systems/components that are out of service during the replacement activity; 3) the deployment manager 1013 so that the software processes that are impacted by the replacement activity (e.g., jobs, virtual machines, containers) can be parked or moved to other electronic processing resources.

So doing allows for smooth shut down of isolated platform resources during component replacement without crashing jobs/applications/containers that were relying on the resources before the replacement. In various embodiments, the maintenance schedule for any/all components defines a window of time in which the component, and any associated resources that are electrically and/or mechanically coupled to the component, will be down (unavailable) because of the component's replacement.

For example, if a processor is to be replaced, the processor's cooling system will also be brought down during the processor replacement (the processor's cooling apparatus must be removed in order to remove the processor). If the cooling system is designed such that the cooling fluid that flows through the thermal mass of the processor being replaced also flows through the respective thermal masses of other electrical components, e.g., other processors within the processor's same sled, then, the maintenance schedule schedules the other electrical components to also be down during replacement of the processor. The deployment controller can then park and/or move jobs from the group of processors before the processor is replaced so that crashes are avoided.

Although embodiments above have focused on three different cooling mechanisms (air, liquid and chilled liquid), the above teaching mechanisms can be applied to more than three different cooling mechanisms and/or other cooling mechanisms than those described above (e.g., immersion cooling).

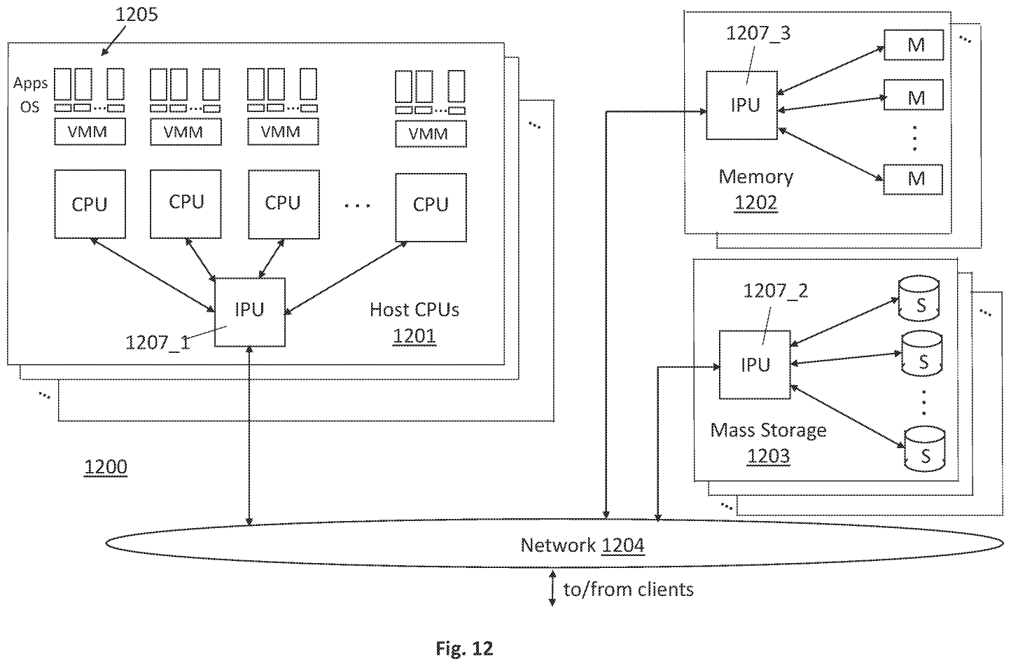

FIG. 12 shows a new, emerging computing environment (e.g., data center) paradigm in which “infrastructure” tasks are offloaded from traditional general purpose “host” CPUs (where application software programs are executed) to an infrastructure processing unit (IPU), data processing unit (DPU) or smart networking interface card (SmartNIC), any/all of which are hereafter referred to as an IPU.

Networked based computer services, such as those provided by cloud services and/or large enterprise data centers, commonly execute application software programs for remote clients. Here, the application software programs typically execute a specific (e.g., “business”) end-function (e.g., customer servicing, purchasing, supply-chain management, email, etc.).

Remote clients invoke/use these applications through temporary network sessions/connections that are established by the data center between the clients and the applications. A recent trend is to strip down the functionality of at least some of the applications into more finer grained, atomic functions (“micro-services”) that are called by client programs as needed. Micro-services typically strive to charge the client/customers based on their actual usage (function call invocations) of the micro-service application.

In order to support the network sessions and/or the applications' functionality, however, certain underlying computationally intensive and/or trafficking intensive functions (“infrastructure” functions) are performed.

Examples of infrastructure functions include encryption/decryption for secure network connections, compression/decompression for smaller footprint data storage and/or network communications, virtual networking between clients and applications and/or between applications, packet processing, ingress/egress queuing of the networking traffic between clients and applications and/or between applications, ingress/egress queueing of the command/response traffic between the applications and mass storage devices, error checking (including checksum calculations to ensure data integrity), distributed computing remote memory access functions, etc.

Traditionally, these infrastructure functions have been performed by the CPU units “beneath” their end-function applications. However, the intensity of the infrastructure functions has begun to affect the ability of the CPUs to perform their end-function applications in a timely manner relative to the expectations of the clients, and/or, perform their end-functions in a power efficient manner relative to the expectations of data center operators. Moreover, the CPUs, which are typically complex instruction set (CISC) processors, are better utilized executing the processes of a wide variety of different application software programs than the more mundane and/or more focused infrastructure processes.

As such, as observed in FIG. 12, the infrastructure functions are being migrated to an infrastructure processing unit. FIG. 12 depicts an exemplary data center environment 1200 that integrates IPUs 1207 to offload infrastructure functions from the host CPUs 1201 as described above.

As observed in FIG. 12, the exemplary data center environment 1200 includes pools 1201 of CPU units (e.g., multicore processors) that execute the end-function application software programs 1205 that are typically invoked by remotely calling clients. The data center 1200 also includes separate memory pools 1202 and mass storage pools 1205 to assist the executing applications. The CPU, memory storage and mass storage pools 1201, 1202, 1203 are respectively coupled by one or more networks 1204.

Notably, each pool 1201, 1202, 1203 has an IPU 1207_1, 1207_2, 1207_3 on its front end or network side. Here, each IPU 1207 performs pre-configured infrastructure functions on the inbound (request) packets it receives from the network 1204 before delivering the requests to its respective pool's end function (e.g., executing software in the case of the CPU pool 1201, memory in the case of memory pool 1202 and storage in the case of mass storage pool 1203). As the end functions send certain communications into the network 1204, the IPU 1207 performs pre-configured infrastructure functions on the outbound communications before transmitting them into the network 1204.

Depending on implementation, one or more CPU pools 1201, memory pools 1202, mass storage pools 1203 and network 1204 can exist within a single chassis, e.g., as a traditional rack mounted computing system (e.g., server computer). In a disaggregated computing system implementation, one or more CPU pools 301, memory pools 1202, and mass storage pools 1203 are, e.g., separate rack mountable units (e.g., rack mountable CPU units, rack mountable memory units (M), rack mountable mass storage units (S)). Although not depicted in FIG. 12, an additional accelerator pool could also be coupled to the network 1204 through its own IPU similar to the other pools. The accelerator pool can include, e.g., any separate rack mountable units of any combination of GPUs, artificial intelligence inference semiconductor chips, artificial intelligence semiconductor chips, etc.

In various embodiments, the software platform on which the applications 1205 are executed include a virtual machine monitor (VMM), or hypervisor, that instantiates multiple virtual machines (VMs). Operating system (OS) instances respectively execute on the VMs and the applications execute on the OS instances. Alternatively or combined, container engines (e.g., Kubernetes container engines) respectively execute on the OS instances. The container engines provide virtualized OS instances and containers respectively execute on the virtualized OS instances. The containers provide isolated execution environment for a suite of applications which can include, applications for micro-services.

Notably, each pool can be viewed as its own respective data center that the improvements of FIGS. 6, 9 and 10 are applied to. For example, the dispatcher dispatches jobs to application software programs that execute in containers in the case of a CPU pool, the dispatcher dispatches read/write request “jobs” to memory hardware units (e.g., DIMMs) and/or mass storage hardware units (e.g., SSDs) in the case of a memory and/or mass storage pool, the dispatcher dispatches accelerator functional call invocation “jobs” in the case of an accelerator pool. That is, the electronic systems 601, 901, 1001 of FIGS. 6, 9 and 10 include CPU processors in the case of a CPU pool, memory DIMMs in the case of a memory pool, SSDs in the case of a mass storage pool and accelerator semiconductor chips in the case of an acceleration pool.

Moreover, e.g., in the case of a large pool, there can be many IPUs that service a single pool. Here, the electronic systems of claims 601, 901, 1001 correspond to the pool's IPUs that process packets that are directed to/from the pool as described above.

With respect to FIG. 10, in the case of memory pools, the deployment controller 1013 controls which memory hardware units (e.g., DIMMs, sleds of DIMMs, etc.) in the pool are enabled and able to receive memory access requests. In the case of mass storage pools, the deployment controller 1013 controls which mass storage hardware units in the pool (e.g., SSDs, sleds of SSDs, etc.) are enabled and able to receive mass storage access requests. In the case of acceleration pools, the deployment controller 1013 controls which acceleration hardware units in the pool (e.g., acceleration chips, sleds of acceleration chips, etc.) are enabled and able to receive acceleration requests. In the case of collections of IPUs, the deployment controller 1013 controls which IPUs (e.g., IPUs chips, sleds of IPUs, etc.) are enabled and able to receive requests/responses to/from the IPU's respective pool.

With respect to FIGS. 6, 9 and 10 any/all of the cooling controller 611, 911, 1011; dispatcher 613, 913; A.I and workload prediction functions 914, 1014, 1014, 1015; and deployment controller 1013 can be implemented, e.g., as software programs that execute on CPU processors (such as within CPU pool 1201); with programmable logic such as one of more field programmable gate arrays (FPGAs); with dedicated, hardwired (e.g., ASIC) circuitry, or any combination of these. The same is true for the failure prediction function 1101 and maintenance controller 1104 of FIG. 11.

The teachings above can also be applied to traditional data centers, e.g., where the racks contain individual servers installed therein and the dispatcher dispatches jobs, e.g., to the applications that run within the servers.

Embodiments of the invention may include various processes as set forth above. The processes may be embodied in program code (e.g., machine-executable instructions). The program code, when processed, causes a general-purpose or special-purpose processor to perform the program code's processes. Alternatively, these processes may be performed by specific/custom hardware components that contain hard wired interconnected logic circuitry (e.g., application specific integrated circuit (ASIC) logic circuitry) or programmable logic circuitry (e.g., field programmable gate array (FPGA) logic circuitry, programmable logic device (PLD) logic circuitry) for performing the processes, or by any combination of program code and logic circuitry.

Elements of the present invention may also be provided as a machine-readable medium for storing the program code. The machine-readable medium can include, but is not limited to, floppy diskettes, optical disks, CD-ROMs, and magneto-optical disks, FLASH memory, ROMs, RAMs, EPROMs, EEPROMs, magnetic or optical cards or other type of media/machine-readable medium suitable for storing electronic instructions.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. A method, comprising:
dispatching jobs across electronic hardware components, the electronic hardware components to process the jobs, the electronic hardware components coupled to respective cooling systems, the respective cooling systems each capable of cooling according to different cooling mechanisms, the different cooling mechanisms having different performance and cost operating realms, the dispatching of the jobs comprising assigning the jobs to specific ones of the electronic hardware components to keep the cooling systems operating in one or more of the realms having lower performance and cost than another one of the realms.

2. The method of claim 1 wherein the electronic hardware components are racks with electronic systems installed therein.

3. The method of claim 1 wherein the electronic components are electronic systems installed within a rack.

4. The method of claim 1 wherein the method further comprises:
monitoring respective workloads of the electronic hardware components;
recognizing from the monitoring that processing activity of one of the jobs has increased, the one job executing on one of the electronic hardware components;
moving the one job from the one electronic hardware component to another one of the electronic hardware components to keep the one electronic hardware component's respective cooling system operating in the one realm.

5. The method of claim 1 wherein the method further comprises:
monitoring respective workloads of the electronic hardware components;
predicting from the monitoring that processing activity of one of the jobs will increase, the one job executing on one of the electronic hardware components;
moving the one job from the one electronic hardware component to another one of the electronic hardware components to keep the one electronic hardware component's respective cooling system operating in the one realm.

6. The method of claim 1 wherein the method further comprises:
monitoring respective workloads of the electronic hardware components;
predicting from the monitoring a failure of a component within one of the electronic hardware components or one of the cooling systems;
scheduling a replacement time for the component;
before the replacement time, parking and/or moving a subset of the jobs that are affected by the component's replacement.

7. The method of claim 1 wherein the dispatching of jobs is to prevent any one of the cooling systems from operating in a first of the realms until all of the cooling systems are operating in a second of the realms, the second of the realms having an immediately lower performance and cost than the first of the realms.

8. One or more machine readable storage media containing program code that when processed by one or more processors causes a method to be performed, the method comprising:
dispatching jobs across electronic hardware components, the electronic hardware components to process the jobs, the electronic hardware components coupled to respective cooling systems, the respective cooling systems each capable of cooling according to different cooling mechanisms, the different cooling mechanisms having different performance and cost operating realms, the dispatching of the jobs comprising assigning the jobs to specific ones of the electronic hardware components to keep the cooling systems operating in one or more of the realms having lower performance and cost than another one of the realms.

9. The one or more machine readable storage media of claim 8 wherein the electronic hardware components are racks with electronic systems installed therein.

10. The one or more machine readable storage media of claim 8 wherein the electronic components are electronic systems installed within a rack.

11. The one or more machine readable storage media of claim 8 wherein the method further comprises:
monitoring respective workloads of the electronic hardware components;
recognizing from the monitoring that processing activity of one of the jobs has increased, the one job executing on one of the electronic hardware components;
moving the one job from the one electronic hardware component to another one of the electronic hardware components to keep the one electronic hardware component's respective cooling system operating in the one realm.

12. The one or more machine readable storage media of claim 8 wherein the method further comprises:
monitoring respective workloads of the electronic hardware components;
predicting from the monitoring that processing activity of one of the jobs will increase, the one job executing on one of the electronic hardware components;
moving the one job from the one electronic hardware component to another one of the electronic hardware components to keep the one electronic hardware component's respective cooling system operating in the one realm.

13. The one or more machine readable storage media of claim 8 wherein the method further comprises:
monitoring respective workloads of the electronic hardware components;
predicting from the monitoring a failure of a component within one of the electronic hardware components or one of the cooling systems;
scheduling a replacement time for the component;
before the replacement time, parking and/or moving a subset of the jobs that are affected by the component's replacement.

14. The one or more machine readable storage media of claim 8 wherein the dispatching of jobs is to prevent any one of the cooling systems from operating in a first of the realms until all of the cooling systems are operating in a second of the realms, the second of the realms having an immediately lower performance and cost than the first of the realms.

15. A data center, comprising:
a CPU pool comprising electronic hardware components;
a memory pool;
an accelerator pool;
a network communicatively coupling the CPU pool, the memory pool and the accelerator pool; and,
one or more machine readable storage media containing program code that when processed by one or more processors causes a method to be performed, the method comprising:
dispatching jobs across the electronic hardware components, the electronic hardware components to process the jobs, the electronic hardware components coupled to respective cooling systems, the respective cooling systems each capable of cooling according to different cooling mechanisms, the different cooling mechanisms having different performance and cost operating realms, the dispatching of the jobs comprising assigning the jobs to specific ones of the electronic hardware components to keep the cooling systems operating in one or more of the realms having lower performance and cost than another one of the realms.

16. The data center of claim 15 wherein the method further comprises:
monitoring respective workloads of the electronic hardware components;
recognizing from the monitoring that processing activity of one of the jobs has increased, the one job executing on one of the electronic hardware components;
moving the one job from the one electronic hardware component to another one of the electronic hardware components to keep the one electronic hardware component's respective cooling system operating in the one realm.

17. The data center of claim 15 wherein the method further comprises:
monitoring respective workloads of the electronic hardware components;
predicting from the monitoring that processing activity of one of the jobs will increase, the one job executing on one of the electronic hardware components;
moving the one job from the one electronic hardware component to another one of the electronic hardware components to keep the one electronic hardware component's respective cooling system operating in the one realm.

18. The data center of claim 15 wherein the method further comprises:
monitoring respective workloads of the electronic hardware components;
predicting from the monitoring a failure of a component within one of the electronic hardware components or one of the cooling systems;
scheduling a replacement time for the component;
before the replacement time, parking and/or moving a subset of the jobs that are affected by the component's replacement.

19. The data center of claim 15 wherein the dispatching of jobs is to prevent any one of the cooling systems from operating in a first of the realms until all of the cooling systems are operating in a second of the realms, the second of the realms having an immediately lower performance and cost than the first of the realms.

20. The data center of claim 15 wherein the jobs are executed within containers deployed on the electronic hardware components.
